(19) United States
(12) Patent Application Publication
(10) Pub. No.: US 2011/0115052 A1
(43) Pub. Date: May 19, 2011

(54) SEMICONDUCTOR DEVICE AND METHOD OF MANUFACTURING THE SAME

(75) Inventor: Shigeru SUGIOKA, Chuo-ku (JP)

(73) Assignee: ELPIDA MEMORY, INC., Tokyo (JP)

(21) Appl. No.: 12/947,563

(22) Filed: Nov. 16, 2010

(30) Foreign Application Priority Data
Nov. 17, 2009 (JP) 2009-261927

(51) Int. Cl. H01L 27/02; H01L 21/20

(52) U.S. Cl. 257/532; 438/393; 257/E27.009; 257/E21.09

(57) ABSTRACT

A semiconductor device including a capacitor having a lower electrode in which the lower electrode includes a first cylindrical lower electrode connected to a contact electrically connected to a semiconductor substrate; and a second cylindrical lower electrode in contact with an inner wall of at least an upper end of the first cylindrical lower electrode and extending upwards from a top of the first cylindrical lower electrode.

### BACKGROUND OF THE INVENTION

1. Field of the Invention

The invention relates to a semiconductor device and a method of manufacturing the same. In particular, the invention relates to a lower electrode structure of a capacitor in a memory device such as a DRAM device and a method of manufacturing the same.

2. Description of the Related Art

In order to achieve high integration level of a DRAM device, a size of a memory cell needs to decrease. In case the size of the memory cell has reduced, a capacitance of a capacitor in the memory cell is required to have a level equal to or larger than a predetermined level. To this end, it has been conventional that a 3-dimensional structured capacitor electrode is formed by forming a storage node hole in an insulating film on a semiconductor device and then forming a conductive film using an inner wall of the hole as a frame.

In order to increase the capacitance of such a 3-dimensional structured capacitor, a height of the capacitor electrode should increase by forming the storage node hole as deeply as possible.

As an aspect ratio of the hole, however, becomes higher, it is difficult to form the electrode in the storage node hole. That is, if the aspect ratio is high, a bowing profile, when forming the storage node hole, may occur in which a middle portion of the hole becomes wider than upper and lower portions of the hole. Because of the bowing profile, contacts between neighboring storage node holes may be formed. Such contacts cause short circuits between the capacitor electrodes formed on inner walls of the holes, resulting in an abnormal operation of the capacitor. Further, if the aspect ratio of the hole is high, the conductive film may be formed on the inner wall of the hole with poor coverage. In order to avoid such problems, Japanese patent Laid-Open No. 2004-39683 discloses a method of forming the storage node hole with multitiered holes. When forming the multitiered storage node hole, each level of holes becomes one hole with a lower aspect. Accordingly, the bowing profile may be suppressed, and, thus, the short circuits between the capacitor electrodes may be avoided, thereby producing the capacitor electrode providing the predetermined level of the capacitance.

Meanwhile, Japanese patent Laid-Open No. 2003-297952 discloses a crown-shape capacitor in which a lower electrode thereof is formed as a cylinder shape and both of inner and outer walls of the electrode function as a capacitive electrode so that the capacitance in the capacitor might increase. In such an approach, the predetermined level of the capacitance can be acquired, even if the height of the lower electrode makes small. Accordingly, the storage node hole used in forming the lower electrode may have a lower aspect ratio.

In order to further reduce the size of the memory cell, in the crown-shape capacitor as disclosed in Japanese patent Laid-Open No. 2003-297952, the storage node hole used in forming the lower electrode needs to be deeper so that the height of the lower electrode to be formed might be larger. As mentioned above, when the aspect ratio of the hole, however, becomes higher (for example, the aspect ratio of the hole becomes equal to or higher than 20), the bowing profile may occur when forming the storage node hole. To overcome this problem, the crown-shape capacitor may be formed by forming the deeper hole using the method of forming two-tiered storage node hole disclosed as in Japanese patent Laid-Open No. 2004-39683. However, this approach results in a following new problem.

That is, in a case of forming a hole having a two-tiered structure, misalignment between a lower sub-hole and an upper sub-hole may occur, so that there may be formed a steped bump (see “55” in FIG. 9) between the lower sub-hole and upper sub-hole. As a result, when forming the lower electrode, the coverage of the conductive film at the steped bump may become poor, so that the film at the steped bump becomes thin. Accordingly, there may occur deterioration of a mechanical strength of the electrode and increase of an electrical resistance of the electrode at the steped bump. In this situation, an electrode portion at the steped bump is easily breakable when an interlayer insulating film used as a frame as in the crown-shape capacitor is removed. In particular, as disclosed in Japanese patent Laid-Open No. 2003-297952, when a supporting film is formed to prevent the electrode from collapsing when the interlayer insulating film is removed, stress may still concentrate on the film at the steped bump, and, hence, the electrode at the portion of the steped bump may be broken.

Therefore, according to the conventional methods, it is difficult to form a capacitor with large capacitance when the size of the memory cell becomes smaller.

### SUMMARY

According to the invention, a first conductive film (a first lower electrode) is formed so as to cover an inner wall of a first cylinder hole formed in a first interlayer insulting film, and, then, a second interlayer insulating film is formed on the first interlayer insulting film so that a space laterally surrounded with the first conductive film is not filled with the second interlayer insulating film. Thereafter, a second cylinder hole is formed by opening the second interlayer insulating film so that the formed second cylinder hole is positioned on the first cylinder hole. Next, a second conductive film (a second lower electrode) is formed so as to cover an inner wall of the second cylinder hole. In this way, there is provided a lower electrode having a stacked structure in which the second conductive film is stacked on the first conductive film, and, at the same time, has the second lower electrode further extending upwards from a top end of the first lower electrode.

That is, in accordance with one embodiment of the invention, there is provided a semiconductor device including a capacitor having a lower electrode in which the lower electrode includes a first cylindrical lower electrode connected to a contact electrically connected to a semiconductor substrate; and a second cylindrical lower electrode in contact with an inner wall of at least an upper end of the first cylindrical lower electrode and extending upwards from a top of the first cylindrical lower electrode.

In accordance with one embodiment of the invention, there is provided a semiconductor device including a capacitor having a lower electrode in which the lower electrode includes a lower layer having a stacked structure of at least two conductive films and is connected to a contact electrically connected to a semiconductor substrate; and a cylindrical upper layer in which an inner side conductive film among the at least two conductive films extends upwards from a top of the lower layer.

In accordance with one embodiment of the invention, there is provided a method of manufacturing a semiconductor device including a capacitor. The method includes forming, in a first interlayer insulating film formed on a contact electrically connected to a semiconductor substrate, a first cylinder hole exposing a top face of the contact; forming, in the first cylinder hole, a first cylindrical lower electrode connected to the contact; forming a second interlayer insulating film on the first interlayer insulating film so that a space laterally surrounded with the first cylindrical lower electrode is not filled with the second interlayer insulating film; forming a second cylinder hole in the second interlayer insulating film so as to expose an entirety of an aperture of the space laterally surrounded with the first cylindrical lower electrode and expose an inner wall of the first cylindrical lower electrode; and forming a second cylindrical lower electrode continuously extending on and from the inner wall of the first cylindrical lower electrode on and to an inner wall of the second cylinder hole, the second cylindrical lower electrode extending cylindrically at least in the second cylinder hole.

According to the invention, it is not necessary, using an anisotropic dry etching process just one time, to form a storage node hole with high aspect ratio. Therefore, the bowing profile can be suppressed and thus the hole can be formed with a desired shape. At the same time, the conductive film is prevented from being thin at the boundary portion between the upper and lower sub-holes of the storage node hole, and, thus, the mechanical strength of the lower electrode can be enhanced. Further, the increase of the electrical resistance of the lower electrode can be suppressed.

Therefore, the invention facilitates producing the DRAM device with smaller dimension and thus achieving the high integration level of the DRAM device.

### BRIEF DESCRIPTION OF THE DRAWINGS

The above features and advantages of the present invention will be more apparent from the following description of certain exemplary embodiments taken in conjunction with the accompanying drawings, in which:

FIG. 1 to FIG. 5, FIG. 7 to FIG. 8, FIG. 10 to FIG. 12, FIG. 14 and FIG. 15 are cross-sectional views of one exemplary embodiment of a process of manufacturing a semiconductor device according to the invention;

FIG. 6 is a top view of one exemplary embodiment of the process of manufacturing the semiconductor device according to the invention;

FIG. 9 is a cross-sectional view of a comparison example in which a first lower electrode is not formed, in advance, in a first cylinder hole and a first groove;

FIG. 13 is a top view of one exemplary embodiment of the process of manufacturing the semiconductor device according to the invention;

FIG. 16 and FIG. 17 are cross-sectional views of another exemplary embodiment of a process of manufacturing a semiconductor device according to the invention;

FIG. 18 and FIG. 22 are cross-sectional views of still another exemplary embodiment of a process of manufacturing a semiconductor device according to the invention.

### DETAILED DESCRIPTION OF THE EXEMPLARY EMBODIMENTS

The invention will be now described herein with reference to exemplary embodiments. Those skilled in the art will recognize that many alternative embodiments can be accomplished using the teachings of the present invention and that the invention is not limited to the embodiments illustrated for explanatory purpose.

### First Exemplary Embodiment

One exemplary embodiment in which the DRAM device having a cylindrical capacitor in a memory cell is formed using a method of manufacturing a semiconductor device according to the invention will be now described with reference to the drawings. In those drawings, a left side shows an end portion of a memory cell region and a peripheral circuit region while a right side shows a central region of the memory cell region.

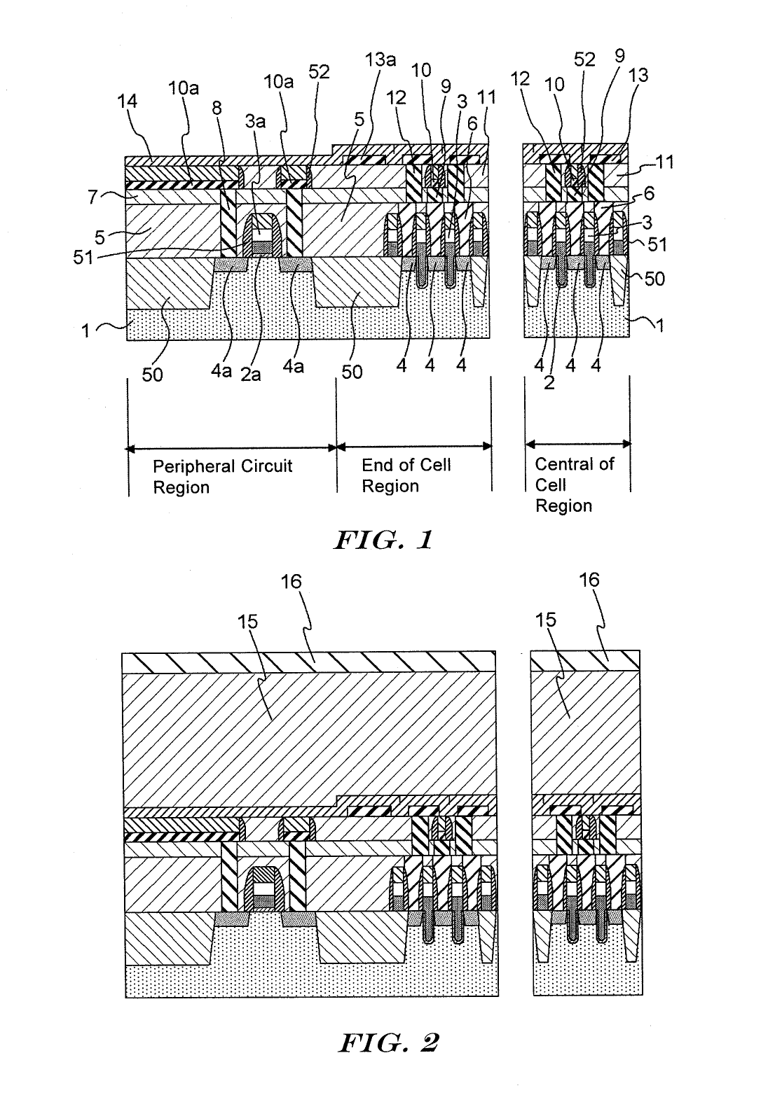

As shown in FIG. 1, a structure in which a MOS transistor formed in/on semiconductor substrate 1 such as a silicon substrate is provided.

In this exemplary embodiment, the MOS transistor having a recess gate electrode is disposed in the memory cell region while the MOS transistor having a planar gate electrode is disposed in the peripheral circuit region. Each transistor is formed in active regions of semiconductor substrate 1, and the active regions are isolated from each other by device isolation region 50 using STI (Shallow Trench Isolation).

In the MOS transistor having the recess gate electrode disposed in the memory cell region, a part of gate electrode 3 is placed in a groove (recess) so as to face away semiconductor substrate 1 via gate insulating film 2 formed in the groove. In the MOS transistor having the planar type gate electrode disposed in the peripheral circuit region, gate electrode 3a is formed so as to face away semiconductor substrate 1 via gate insulating film 2a formed in the top surface of semiconductor substrate 1. Gate electrodes 3, 3a are formed as a stacked conductive structure in which a metal film such as a tungsten (W) film is stacked on a polysilicon film doped with impurities. A protection insulating film is formed on the top surface of the stacked conductive structure. Side wall 15 made of a nitride film is formed on a side wall of the gate electrode.

In the active regions at which gate electrodes 3, 3a are not formed, there are formed diffusion layer 4 (in the memory cell region) and diffusion layer 4a (in the peripheral circuit region) doped with impurities. Those diffusion layers 4, 4a function as source/drain regions of the respective MOS transistor. Gate electrode 3 in the memory cell region functions as a word line of the DRAM device.

Interlayer insulating film 5 is formed so as to cover the transistors. Material of interlayer insulating film 5 includes silicon oxide (SiO₂) which is formed by a CVD (chemical vapor deposition) method or using SOD (spin on dielectric) as coated insulating material. Thereafter, the top face of interlayer insulating film 5 is planarized using a CMP (chemical mechanical polishing) method.

A photoresist film applied on interlayer insulating film 5 is exposed and developed to form a mask pattern for forming a contact hole on diffusion layer 4 in the memory cell region. A first hole (not shown) penetrating through interlayer insulating film 5 is formed by performing dry etching of interlayer insulating film 5 using the mask pattern. The first hole is filled with a conductive film such as a polysilicon film doped with impurities and the top face of the conductive film is polished using a CMP method, thereby forming cell contact plugs 6 which is connected to diffusion layer 4. In forming cell contact plug 6, the self-alignment technique using side wall 51 may be employed as well.

Interlayer insulating film 7 made of a silicon oxide film is formed on interlayer insulating film 5 using a CVD method. Peripheral contact plugs 8 penetrating through interlayer insulating films 5, 7 are formed so as to be in contact with diffusion layer 4a in the peripheral circuit region. Peripheral contact plugs 8 can be made of conductive material such as tungsten W.

Bit contact plug 9 penetrating through interlayer insulating films 7 is formed so as to be in contact with cell contact plug 6 in the memory cell region. Bit contact plug 9 can be made of conductive material such as tungsten W.

Bit line 10 is formed in the memory cell region. First, a tungsten film with about 50 nm thickness is formed on interlayer insulating films 7 and then a silicon nitride film with about 250 nm thickness is formed on the tungsten film (the silicon nitride film being used as a mask in patterning the tungsten film using dry etching and serving as the surface protection film). Next, the tungsten film is patterned by using the lithography and dry etching technique.

Bit line 10 is connected to bit contact plug 9. Meanwhile, peripheral interconnection layer 10a is formed in the peripheral circuit region by patterning the conducive film (namely, the tungsten film) being the same as that used in forming bit line 10. Peripheral interconnection layer 10a is connected to peripheral contact plug 8. Side walls 52 made of an insulating film such as a silicon nitride film are formed on the side walls of bit line 10 and peripheral interconnection layer 10a.

Interlayer insulating film 11 made of a silicon oxide film is formed on interlayer insulating film 7 using a CVD method. The top face of interlayer insulating film 11 is planarized using a CMP (chemical mechanical polishing) method. At this time, the silicon nitride film is used as a stopper. The CMP method is carried out until a final thickness of the silicon oxide film becomes 70 nm.

A photoresist film applied on interlayer insulating film 11 is exposed and developed to form a mask pattern for forming a contact hole on cell contact plug 6 to which bit contact plug 9 is not connected. A second hole (not shown) penetrating through interlayer insulating films 11, 7 is formed by performing dry etching of interlayer insulating film 11, 7 using the mask pattern. The second hole is filled with a conductive film such as a tungsten (W) film and then the top face of the conductive film is polished using a CMP method, thereby forming capacitive contact plugs 12 which are connected to cell contact plugs 6.

Capacitive contact pads 13 are formed in the memory cell region by forming a tungsten film with about 50 nm thickness on interlayer insulating films 11 and next patterning the tungsten film using the lithography and dry etching technique. Capacitive contact pads 13 are connected to capacitive contact plugs 12. In the end portion of the memory cell region, capacitive contact pad 13a is formed with a width set so as to surround the periphery of the memory cell region. In the invention, a combination of capacitive contact plugs 12 and capacitive contact pads 13 is defined as capacitive contacts.

As stopper film 14 to be used in following dry etching in order that a given depth is generated just one time in forming a cylinder hole as will be described later, a silicon nitride film with about 50 nm thickness is formed using a CVD method so as to cover capacitive contact pads 13, 13a.

As shown in FIG. 2, first interlayer insulating film 15 is formed on stopper film 14 by depositing a silicon oxide film with about 1 μm thickness using a CVD method. Otherwise, first interlayer insulating film 15 can be made of a stack of a BPSG (Boro Phospho Silicate Glass) film and a silicon oxide film.

As first supporting film 16, a silicon nitride film with about 100 nm is formed using a CVD method on first interlayer insulating film 15.

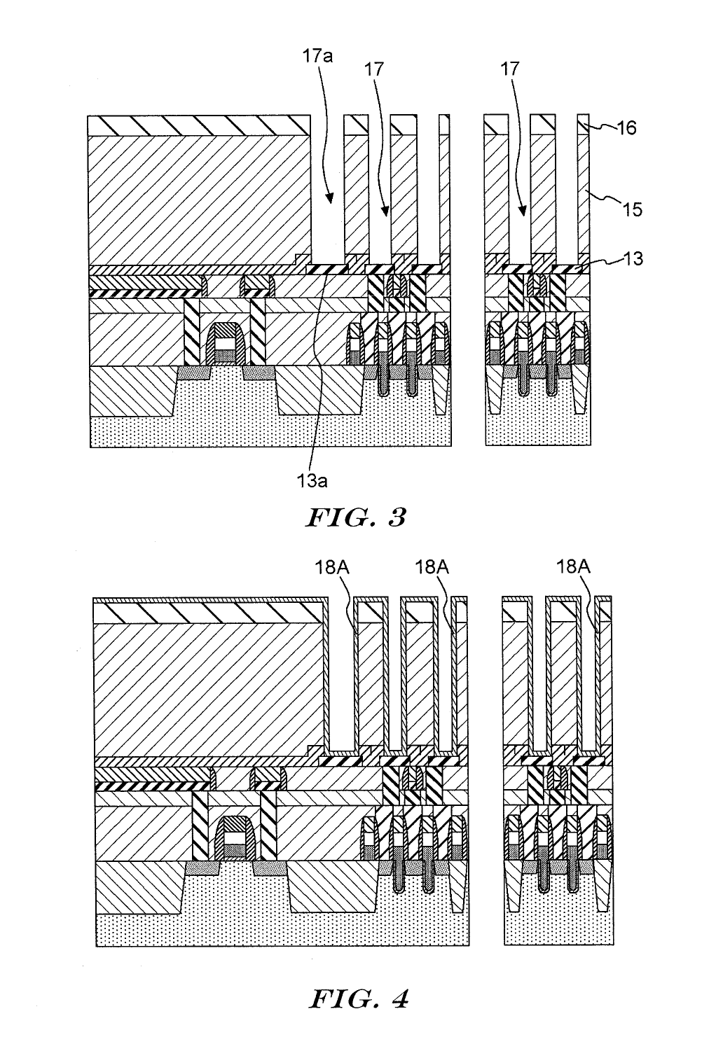

As shown in FIG. 3, at positions in which lower electrodes of the capacitor will be formed, first cylinder holes 17 are formed so as to penetrate through stopper film 14, first interlayer insulating film 15 and first supporting film 16. First cylinder holes 17 expose the top faces of capacitive contact pads 13. At the same time, first groove 17a is formed with a predetermined width so as to surround the periphery of the memory cell region. First groove 17a penetrates through first interlayer insulating film 15 and first supporting film 16 and exposes the top face of capacitive contact pad 13a. First groove 17a may be formed in a separate step from the step for forming first cylinder holes 17 though a number of steps may increase.

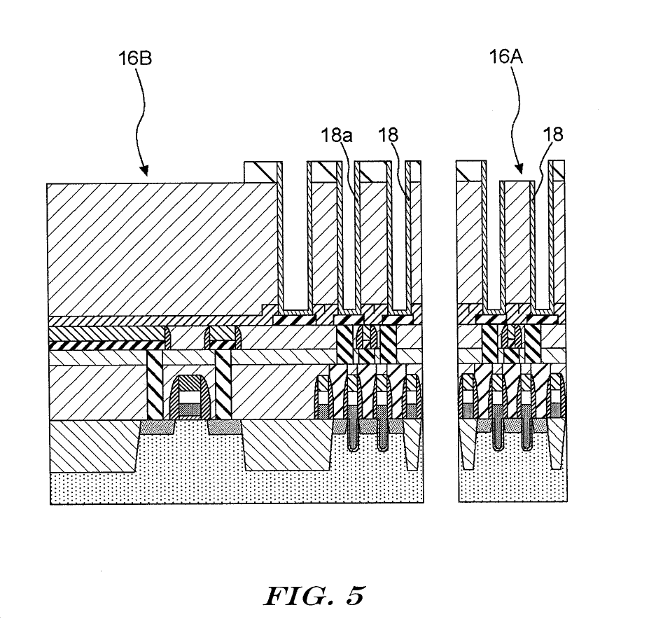

As show in FIG. 4, side walls and bottoms of first cylinder holes 17 and first groove 17a are covered with conductive film 18A. Conductive film 18A has a stacked structure in which a titanium (Ti) film with 5 nm thickness is formed on first supporting film 16 using a CVD method for example under temperature of 600 to 700° C. and then a nitride titanium (TiN) film with 5 to 10 nm thickness is formed on the titanium film using a CVD method for example under temperature of 600 to 700° C. Conductive film 18A covers side walls of first supporting film 16. Instead of the stacked structure, a single film may be employed as conductive film 18A.

As shown in FIG. 5, by removing conductive film 18A on first supporting film 16 so that conductive film 18A on the side walls and bottoms of first cylinder holes 17 and first groove 17a remains, first cylindrical lower electrodes 18 in first cylinder holes 17 and first lower electrode 18a with a gutter shape in first groove 17a are formed.

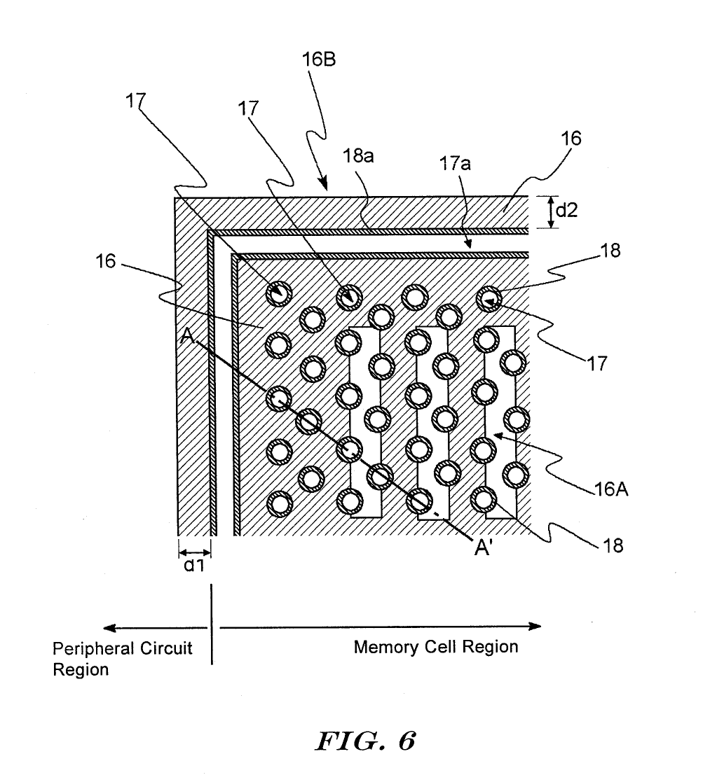

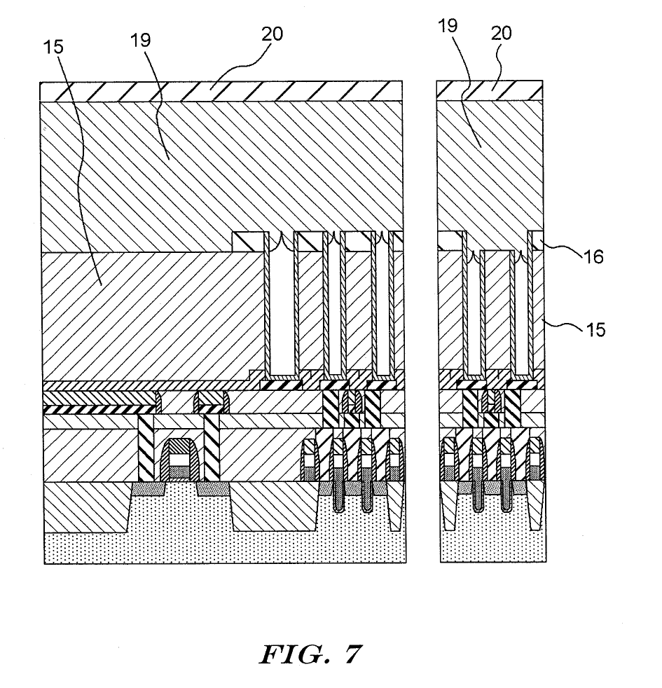

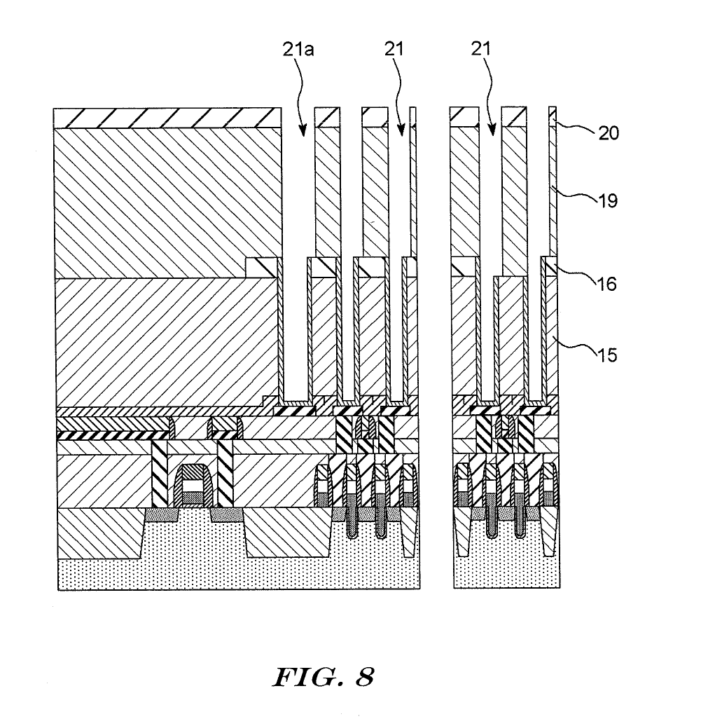

In forming the lower electrodes, as shown in FIG. 6, an openings pattern penetrating through first supporting film 16 and conductive film 18A and then reaching first interlayer insulating film 15 is formed by performing lithography and etching techniques using a mask pattern for forming a first supporting film pattern which has openings 16A in the memory cell region and openings 16B (which will be described in details later) in the peripheral circuit region. At this time, the etching is performed so that the photoresist film to be used in forming a pattern remains in a filled manner in first cylinder holes 17 and first groove 17a. Subsequently, the photoresist film on the surface used in forming the pattern is removed while the photoresist film remains on the bottoms of first cylinder holes 17 and first groove 17a. Then, the stack of the TiN film and the Ti film is etched back while conductive film 18A is exposed, and, in this way, the remaining portion of conductive film 18A on the surface of first supporting film 16 is removed. At this time, conductive film 18A on the bottoms of first cylinder holes 17 and first groove 17a is protected with the photoresist film. Thereafter, the photoresist film remaining on the bottoms of first cylinder holes 17 and first groove 17a is completely removed.

The remaining portion of conductive film 18A on the surface of first supporting film 16 may be removed using a CMP method. In this case, after forming the first supporting film pattern having openings 16A and openings 16B as shown in FIG. 6, the photoresist film used in forming the first supporting film pattern is completely removed. Then, a filling material (insulating material) for preventing slurry used for the CMP from going into first cylinder holes 17 and first groove 17a is filled again and next the CMP is carried out and then the filling material is removed.

Openings 16A and openings 16B formed by removing portions of the first supporting film will be now described. In order that the etchant invades the memory cell region, a plurality of openings 16A is formed in the memory cell region and at positions where the supporting strength of the first supporting film may not be weakened. The positions or planar layout of openings 16A are not limited in a particular manner. As shown in FIG. 6, in the peripheral circuit region, first supporting film 16 remains with widths (D1, D2) predetermined so as to surround first groove 17a, and is completely removed beyond the width to form openings 16B. The purpose for which first supporting film 16 is completely removed beyond the width to form openings 16B is not that the etchant for removing away the interlayer insulating film may invade the peripheral circuit region but that it becomes easy to perform dry etching of contact holes for forming contact plugs in the peripheral circuit region in a later process. The widths (D1, D2) predetermined so as to surround first groove 17a may be equal to each other.

As shown in FIG. 7, second interlayer insulating film 19 with about 1 μm thickness is formed on first interlayer insulating film 15 and first supporting film 16. At this time, forming conditions for second interlayer insulating film 19 are set in such a way that second interlayer insulating film 19 does not fill the space laterally surrounded with first lower electrodes 18, 18a.

In case the DRAM device is formed with a size smaller than a design rule 55 nm, an inner diameter of first cylinder hole 17 becomes equal to or smaller than approximately 65 nm. An inner width of first groove 17a is in advance set to become equal to or smaller than the inner diameter of first cylinder hole 17. As in the fine hole with an aperture size equal to or smaller than about 150 nm, the aperture is, before the silicon oxide film completely fills the hole, blocked with the silicon oxide film by using a PE-CVD (Plasma Enhanced CVD) method exhibiting resulting poor film coverage. In this way, second interlayer insulating film 19 is formed so that the spaces (holes) laterally surrounded with first lower electrodes 18, 18a are not filled with second interlayer insulating film 19.

In case the storage node hole has high aspect ratio to some extent depending on how smaller the design rule become, the silicon oxide film is hardly formed on the bottoms and the side walls of first lower electrodes 18 if the silicon oxide film is deposited using the PE-CVD method with the poor film coverage. Nevertheless, if the silicon oxide film is formed on the bottoms and the side walls of first lower electrodes 18, the thickness of the film thereon becomes just several nm in order of magnitude. In this case, such a silicon oxide film can be removed by the etching in forming the second cylinder hole or by the following wet etching of the oxide film.

Specifically, in case of the DRAM device with 54 nm of the design rule, second interlayer insulating film 19 is formed by depositing the silicon oxide film under the following conditions:

Film forming method: PE-CVD

Pressure: 400 Pa

Temperature: 380° C.

Process gas (flow rate): TEOS [Tetra Ethyl Ortho Silicate] (225 sccm)/oxygen (2070 sccm)

High frequency power/low frequency power: 420/530 W

As an alternative film forming method, an HDP (High Density Plasma) CVD method can be used in forming the silicon oxide film. For example, second interlayer insulating film 19 is formed, so that the hole is not filled with second interlayer insulating film 19, by depositing the silicon oxide film under the following conditions:

Film forming method: HDP-CVD

Pressure: 0.8 Pa (6 mTorr)

Temperature: 660° C.

Process gas (flow rate): monosilane (150 sccm)/oxygen (244 sccm)/helium (300 sccm)

Source power/bias power: 8000/3800 W

The above conditions are merely examples, and thus the film forming conditions can be set so as to obtain the optimized results depending on the size of the hole and groove.

Second interlayer insulating film 19 need not be completely suppressed from being formed in the space laterally surrounded with first lower electrodes 18, 18a. That is, as long as the cavity remains in the space laterally surrounded with first lower electrode 18, it is not problematic that second interlayer insulating film 19 is formed, to a little extent, on the bottoms and side walls of first lower electrodes 18, 18a.

Moreover, second interlayer insulating film 19 can be made of a stack of a plurality of films. In this case, the lowest film among the plurality of the films has been formed until the aperture of the hole is blocked, and, then, other films are formed sequentially using different film forming conditions from one another.

In order to improve focus margin necessary in performing the following lithography technique, the top surface of second interlayer insulating film 19 is planarized using a CMP method. Second supporting film 20 is formed on second interlayer insulating film 19 by depositing a silicon nitride film with about 100 nm thickness.

As shown in FIG. 8, second cylinder hole 21 and second groove 21a are formed on first cylinder hole 17 and first groove 17a respectively so as to penetrate through second interlayer insulating film 19 and second supporting film 20. The bottom of second cylinder hole 21 communicates with the top of first cylinder hole 17, thereby exposing first lower electrode 18. At this time, second cylinder hole 21 is formed so as to expose an entirety of the aperture of the space laterally surrounded with the first lower electrode. The bottom of second groove 21a communicates with the top of first groove 17a, thereby exposing first lower electrode 18a. In the invention, the second interlayer insulating film is formed so that at least the space laterally surrounded with the first lower electrode is not filled with the second interlayer insulating film, and, hence, it is not necessary to form a cylinder hole with high aspect ratio using the dry etching by which the second cylinder hole is formed. For this reason, the bowing profile can be prevented from occurring in the cylinder hole. Even when second interlayer insulating film 19 is formed, to a little extent, on the bottoms and side walls of first lower electrodes 18, 18a as mentioned above with reference to FIG. 7, such a second interlayer insulating film can be removed by the dry etching used in forming the second cylinder hole.

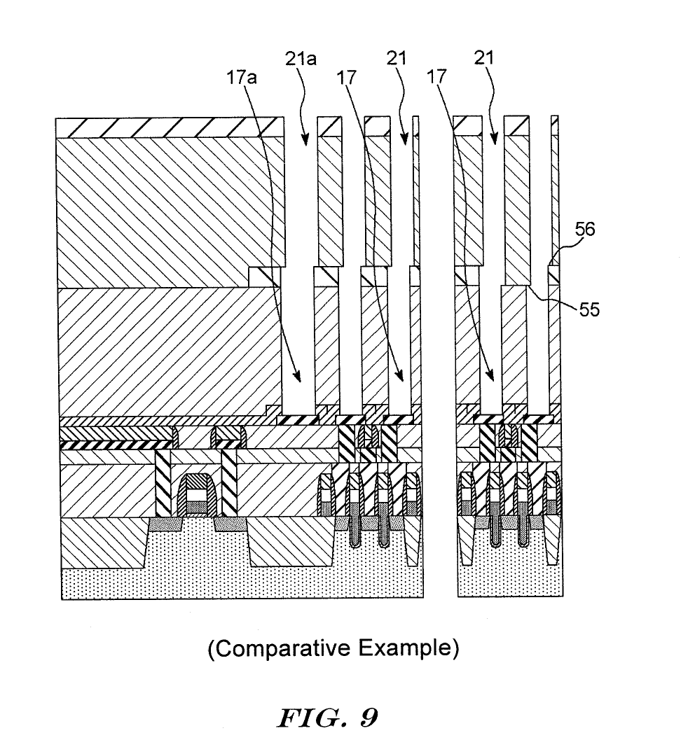

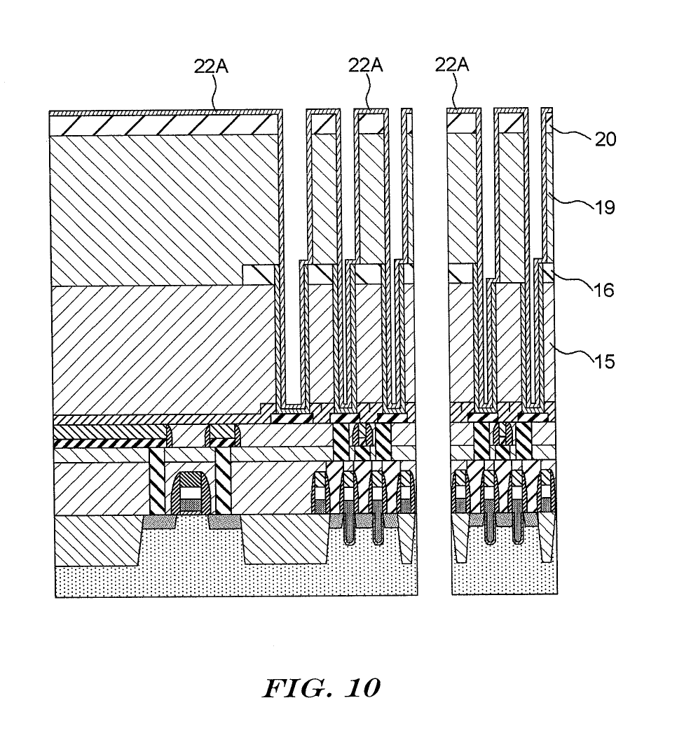

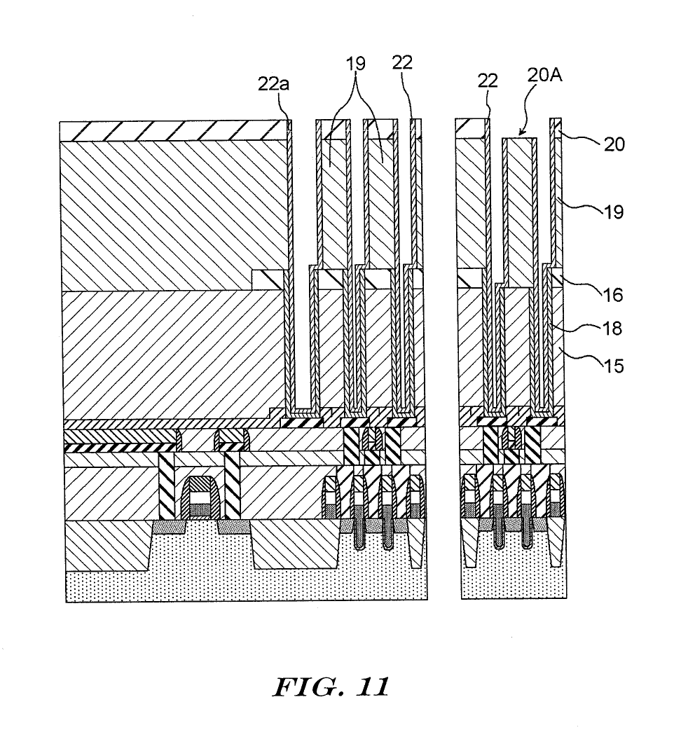

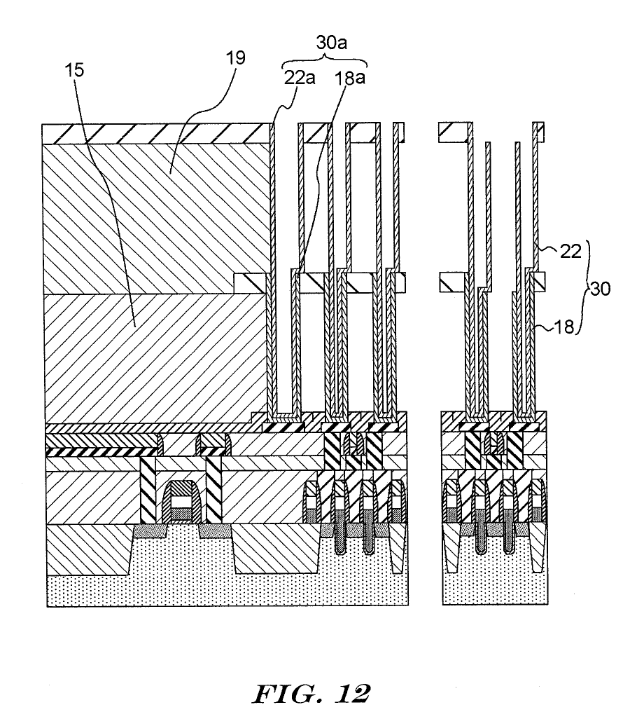

Herein, a cross-sectional view of a comparative example in which first lower electrodes 18, 18a are not formed, in advance, in first cylinder hole 17 and first groove 17a is shown in FIG. 9. Generally, there may occur the alignment deviation (for example, about 5 nm) between the first and second cylinder holes when forming second cylinder hole 21. Therefore, there are formed stepped bumps (55, 56) at the boundary between the first and second cylinder holes. When, in such a state, the conductive film covering the side walls of the first and second cylinder holes are formed as the lower electrode, the conductive film at stepped bumps 55, 56 becomes thinner, so that the electrical resistance of the electrode becomes increase and at the same time the mechanical strength of the electrode would deteriorate. The conductive film tends to become a lot thinner especially at bump 55 becoming an overhang portion. In the present invention, as compared with such a case, first lower electrode 18 is, in advance, formed in first cylinder hole 17 as shown in FIG. 8, and, hence, the conductive film is prevented from becoming thinner at the boundary between the first and second cylinder holes.

The cylinder hole with the two steps or two sub holes according to the comparative example as shown in FIG. 9 may be formed using the approach as disclosed in Japanese patent Laid-Open No. 2004-39683, that is, by filling first cylinder hole 17 with easily removable material such as SOG film and then forming the second interlayer insulating film on the first interlayer insulating film and next forming second cylinder hole 21 in the second interlayer insulating film and finally removing the filling material in the first cylinder hole using the wet etching. In the invention, the space laterally surrounded with the first lower electrode has higher aspect ratio than the first cylinder hole. Accordingly, it is difficult for the etchant to invade through the second cylinder hole into the space laterally surrounded with the first lower electrode. Therefore, if as in the prior-art method, the space laterally surrounded with the first lower electrode is filled with the filling material and then the filling material is removed using the wet etching, the filling material on the bottom of the first cylinder hole cannot be completely removed. For such a reason, the invention employs not the prior-art method but the approach as described herein.

As show in FIG. 10, conductive film 22A is further formed. Conductive film 22A has a stacked structure in which a titanium (Ti) film with 5 nm thickness is formed on second supporting film 20 using a CVD method for example under temperature of 600 to 700° C. and then a titanium nitride (TiN) film with 10 to 15 nm thickness is formed on the titanium film using a CVD method for example under temperature of 600 to 700° C. Conductive film 22A covers side walls of second cylinder hole 21 and second groove 21a and further covers the inner surfaces of first lower electrodes 18, 18a. Instead of the stacked structure, a single film can be employed as conductive film 22A.

As shown in FIG. 11, second cylindrical lower electrodes 22 are formed relative to second cylinder holes 21 by removing conductive film 22A on second supporting film 20 so that conductive film 22A on the side walls and bottoms of second cylinder holes 21 and second groove 21a remains. Further, second lower electrode 22a with a gutter shape is formed relative to second groove 21a as well. As in the process described with reference to FIG. 5, a photoresist film is filled in second cylinder holes 21 and second groove 21a and then a second supporting film pattern is formed and then conducive film 22A on the surface of the second supporting film is etched back. Otherwise, an insulating material (filling material) is filled again and next CMP is carried out and then the filling material is removed.

In first cylinder hole 17, there is formed thick lower electrode 30 as a stacked structure in which second lower electrode 22 is stacked on first lower electrode 18. Similarly, in first groove 17a, there is formed thick lower electrode (guard ring) 30a as a stacked structure in which second lower electrode 22a is stacked on first lower electrode 18a. In the invention, second lower electrode 22 is stacked on first lower electrode 18 at the boundary between the first and second cylinder holes, and, hence, lower electrode 30 is prevented from becoming thinner at the stepped bump positioned at the boundary differently from the comparative example as shown in FIG. 9.

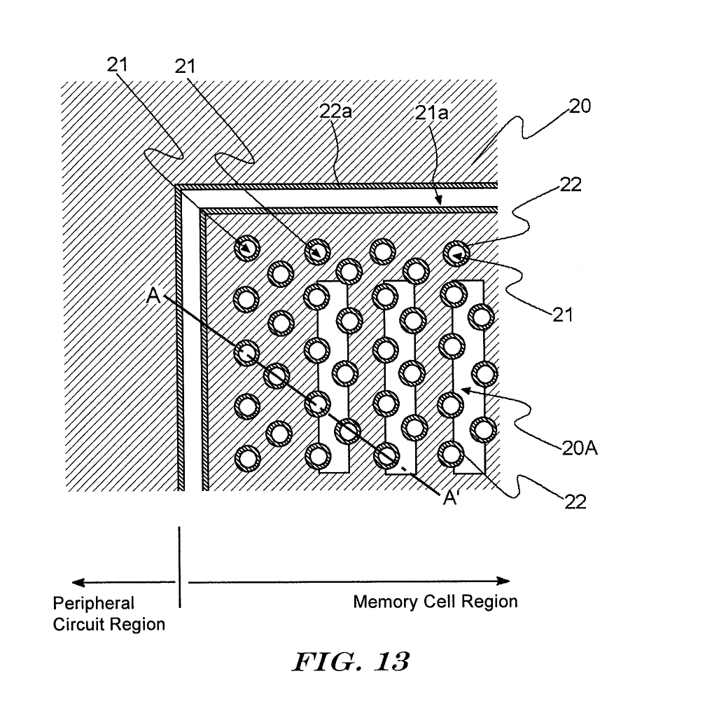

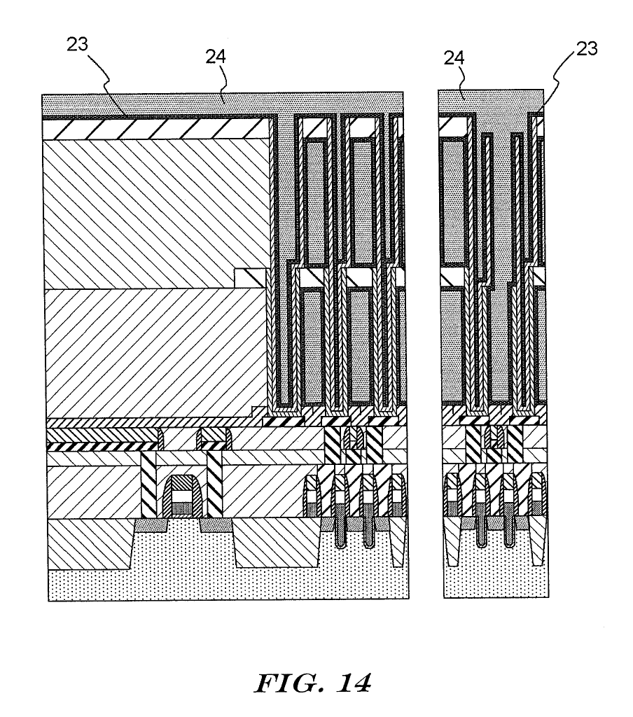

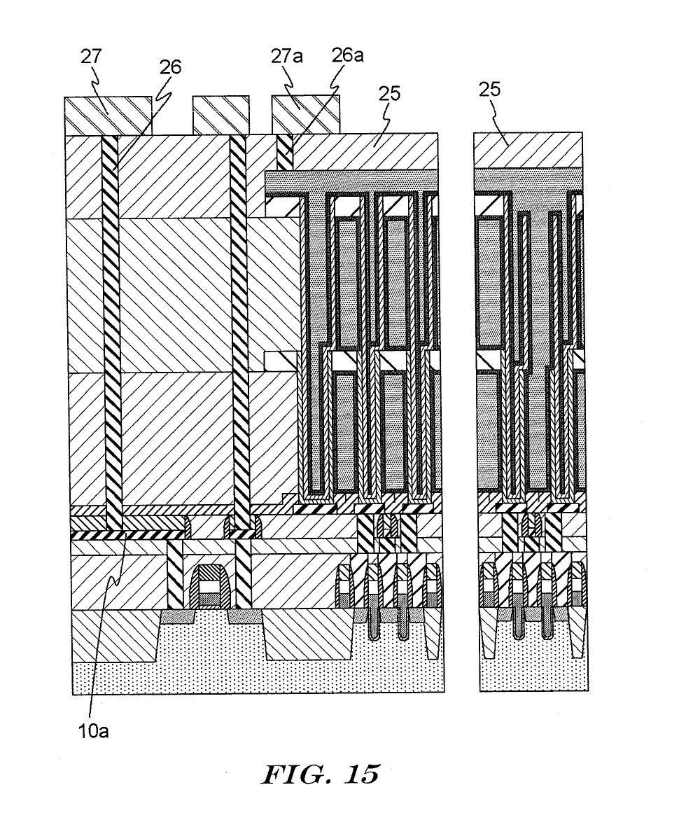

In order to remove the second interlayer insulating film in the memory cell region by using a wet etching with the etchant, a plurality of openings 20A are formed by removing portions of the second supporting film using the lithography and dry etching techniques. As shown in FIG. 13, in the peripheral circuit region, second supporting film 20 is not removed. This is for that the etchant is prevented from invading the peripheral circuit region so that the first and second interlayer insulating films remain in the peripheral circuit region. In this way, second supporting film 20 covers the peripheral circuit region.

As shown in FIG. 12, first and second interlayer insulating films 15, 19 in the memory cell region are removed using the wet etching. At this time, the wet etching conditions are as follows:

Process method: batch type process

Etchant: solution containing hydrofluoric acid (for example, 50 wt % HF)

Etchant temperature: room temperature

Using the wet etching, the outer walls of first and second lower electrodes 18, 22 are exposed. In this way, storage node lower electrode 30 may acquired which is a combination of first and second lower electrodes 18, 22 and whose outer and inner walls are exposed. Stopper film 14 has resistance property against the etchant and hence the etchant does not invade the region below the stopper film.

Although the side wall of lower electrode 30 is exposed, lower electrode 30 is suppressed from collapsing because it is supported with first and second supporting films 16, 30.

FIG. 13 is a plan view of a layout of second groove 21a and second cylinder hole 21 in the end of the memory cell region. In the regions corresponding to openings 20A, second supporting film 20 is removed.

As shown in FIG. 13, although the side wall of second lower electrode 22 is coupled to second supporting film 20, the entirety of the outer side wall of second lower electrode is not laterally surrounded with second supporting film 20 but there are the portion of the outer side wall of the second lower electrode which is not in contact with second supporting film 20. Therefore, second interlayer insulating film 19 can be sufficiently removed by the etchant, though the etchant seems not to invade second interlayer insulating film 19 in FIG. 11, through openings 20A formed in second supporting film 20. This is equally applied to first lower electrode 18 and first supporting film 16. That is, first interlayer insulating film 15 can be sufficiently removed by the etchant, though the etchant seems not to invade first interlayer insulating film 15 in FIG. 11, through openings 16A formed in first supporting film 16.

In the peripheral circuit region, the entire top surface of second interlayer insulating film 19 is covered with second supporting film 20, and the side wall thereof is covered with first and second lower electrodes 18a, 22a formed in first and second grooves 17a, 21a respectively. Accordingly, the etchant used in the wet etching cannot invade the peripheral circuit region.

As shown in FIG. 14, capacitive insulating film 23 is formed on the surfaces of lower electrodes 30, 30a and then upper electrode (plate electrode) 24 made of a titanium nitride film is formed on capacitive insulating film 23. Upper electrode 24 faces away lower electrode 30 via capacitive insulating film 23, resulting in forming the capacitor. A high dielectric film such as zirconium oxide (ZrO₂), aluminum oxide (Al₂O₃) or hafnium oxide (HfO₂); or a stack thereof can be used as capacitive insulating film 23. Upper electrode 24 can be formed in a film structure in which a titanium nitride film is formed with about 10 nm thickness and then the cavity in the hole is filled with a polysilicon film doped with impurities and next a tungsten (W) film with about 100 nm thickness is formed thereon.

As shown in FIG. 15, the unnecessary films (upper electrode 24, capacitive insulating film 23, and second supporting film 20) in the peripheral circuit region are removed using the photolithography and dry etching techniques. Thereafter, upper electrode 24 is covered with third interlayer insulating film 25 and then the top face of third interlayer insulating film 25 is planarized using a CMP method. In the peripheral circuit region, contact plug 26 reaching peripheral interconnection layer 10a and then metal interconnection layer 27 thereon are formed sequentially. Contact plug 26 can be made from tungsten. Metal interconnection layer 27 may employ aluminum (Al) or copper (Cu). Contact plug 26a and metal interconnection layer 27a are formed in the memory cell region so as to connect with a circuit for applying a given voltage to upper electrode 24. Contact plugs 26, 26a can be formed at the same time.

Additional interconnections and electrodes are manufactured on the resulting structure using the above mentioned method and then a protection film covering the surface thereof is formed, whereby completing the DRAM device as the semiconductor device.

According to the method of this exemplary embodiment of the invention, the first lower electrode is formed in the first cylinder hole at the lower level and then the upper interlayer insulating film is formed so as not to fill the space laterally surrounded with the first lower electrode and next the second cylinder hole at the upper level is formed in the upper interlayer insulating film. For this reason, it is not necessary to form the cylinder hole with the high aspect ratio by performing the anisotropic etching only one time and thus it is possible to form the storage node hole with a desired shape. Further, the lower electrode of the capacitor is formed as the partially stacked structure in which at least a portion of the second lower electrode is stacked on the first lower electrode, and, hence, the lower electrode of the capacitor may be prevented from becoming thin. For this reason, the mechanical strength of the lower electrode can be enhanced and further the electrical resistance of the electrode can be prevented from increasing.

### Second Exemplary Embodiment

Other method of manufacturing a semiconductor device according to the invention will now be described with reference to the drawings. In those drawings, a left side shows an end of a memory cell region and a peripheral circuit region while a right side shows a central of the memory cell region.

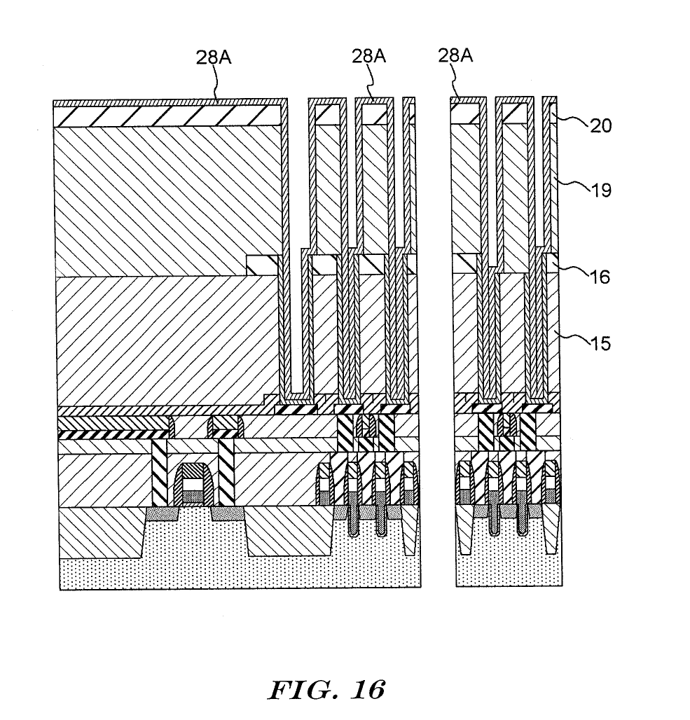

First, the structure including up to second cylinder hole 21 and second groove 21a is formed by performing the same process as in FIG. 1 to FIG. 8 in the first exemplary embodiment. Then, as shown in FIG. 16, conductive film 28A is formed thereon. Conductive film 28A has a stacked structure in which a titanium (Ti) film with 10 nm thickness is formed on the side walls of second cylinder hole 21 and second groove 21 using a CVD method for example under temperature of 600 to 700° C. and then a titanium nitride (TiN) film with 20 to 40 nm thickness is formed on the titanium film using a CVD method for example under the same temperature. It should be noted that this second exemplary embodiment is different from the first exemplary embodiment in that the inner space of first cylinder hole 17 is filled with conductive film 28A so that a combination of conductive film 28A and first lower electrode 18 produces a plug structure. The thickness of conductive film 28A is adjusted depending on the size of the first cylinder hole so as to fill the inner space thereof. The gap or cavity may be formed in first groove 17a. Conductive film 28A can be made of a single or multi-layered film with 40 to 50 nm of total thickness.

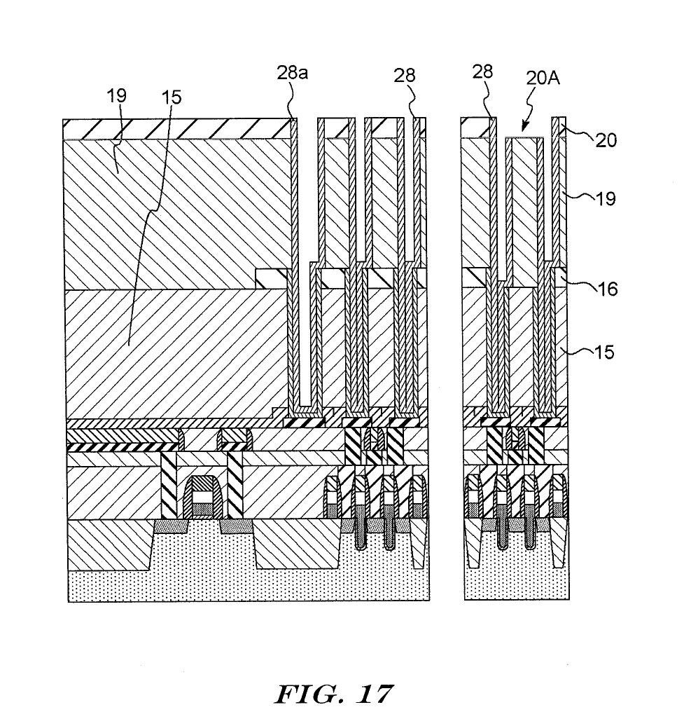

As shown in FIG. 17, second lower electrodes 28, 28a are formed by removing conductive film 28A on second supporting film 20. At this time, the etch-back or the CMP method may be used as in the process of FIG. 5. Openings 20A are formed in second supporting film 20 in order that the etchant might move through the openings 20A.

In a following process, in the same way as in the first exemplary embodiment, first and second interlayer insulating films 15, 19 are removed in the memory cell region using the wet etching. Thereafter, the capacitive insulating film and the upper electrode thereon are formed sequentially, whereby forming the capacitor.

According to the method of this exemplary embodiment, the first lower electrode is formed in the first cylinder hole at the lower level and next the second lower electrode at the upper level is formed so as to completely fill the space laterally surrounded with the first lower electrode. In this way, the lower electrode of the capacitor may be prevented from becoming thinner at the stepped bump and further the mechanical strength of the lower electrode can be enhanced more greatly than in the first exemplary embodiment. Meanwhile, if the first cylinder hole is completely filled from the beginning to form an electrode with a plug structure and then an electrode with a cylindrical shape is connected thereto, the connection portion therebetween may have poor mechanical strength. To the contrary, in this exemplary embodiment, the portion of the second lower electrode is included in a stacked manner in the first lower electrode with the plug structure. For this reason, the deterioration of the mechanical strength of the electrode can be suppressed and further there can be acquired an anchoring effect increasing the strength of the connection portion.

In this exemplary embodiment, in case the size of the capacitor becomes equal to that in the first exemplary embodiment, the capacitance of the capacitor becomes smaller than that in the first exemplary embodiment. Accordingly, with considering the strength and the capacitance of the capacitor necessary in the DRAM device to be employed, the optimized approach for manufacturing the capacitor may be selected.

In this exemplary embodiment, conductive film 28A for forming the second lower electrode becomes thick in order to completely fill the space laterally surrounded with the first lower electrode. However, in order to completely fill the space laterally surrounded with the first lower electrode, conductive film 28A has the same thickness as that in the first exemplary embodiment while the first lower electrode becomes thick. At the latter case, the inner diameter of the second lower electrode becomes less reduced and this contributes the suppression of the reduction of the capacitance. However, if the first lower electrode becomes excessively thick, the connection area between the top face of the first lower electrode and the second lower electrode becomes larger. Accordingly, this may bring about the same situation in which the first lower electrode with the plug structure is formed and then the second lower electrode with the cylinder shape is formed on the first lower electrode. Therefore, it is preferable that the thickness of the first lower electrode is set so as to have the cavity therein whose inner diameter is equal to the thickness of the second lower electrode with cylinder shape. Depending on the inner diameter of the cavity in the first lower electrode or the thickness of the second lower electrode, there may occur the situation in which the cavity is not completely filled with the second lower electrode, that is, the upper end of the cavity is blocked but the bottom portion of the cavity becomes void. However, although such a situation, the anchoring effect can be obtained some extent because the second lower electrode joins to inner surface of the first lower electrode.

Although the lower electrode with the 2 levels of stucking is set forth in the first and second exemplary embodiment, the present invention can be applied to 3 or more levels of stucking. As a number of the levels increase, the probability that, as in the second exemplary embodiment, the space laterally surrounded with the electrode in the lower level is completely filled with the electrode material in the upper level can increase.

### Third Exemplary Embodiment

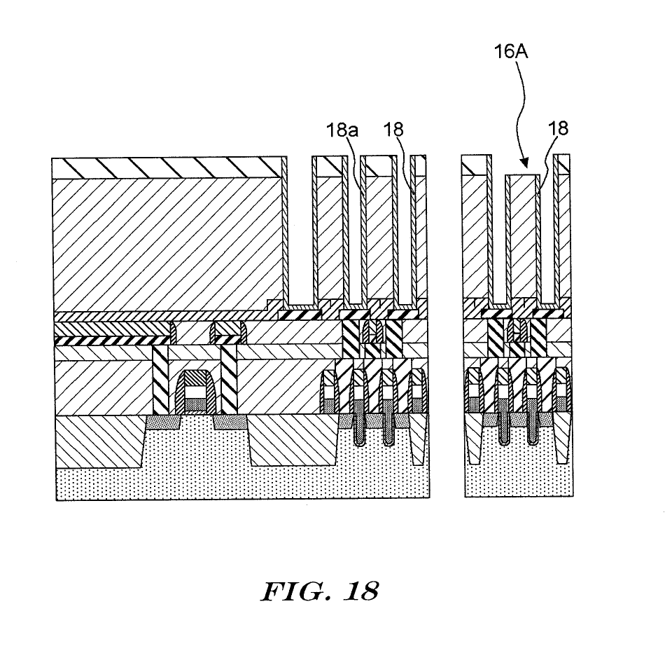

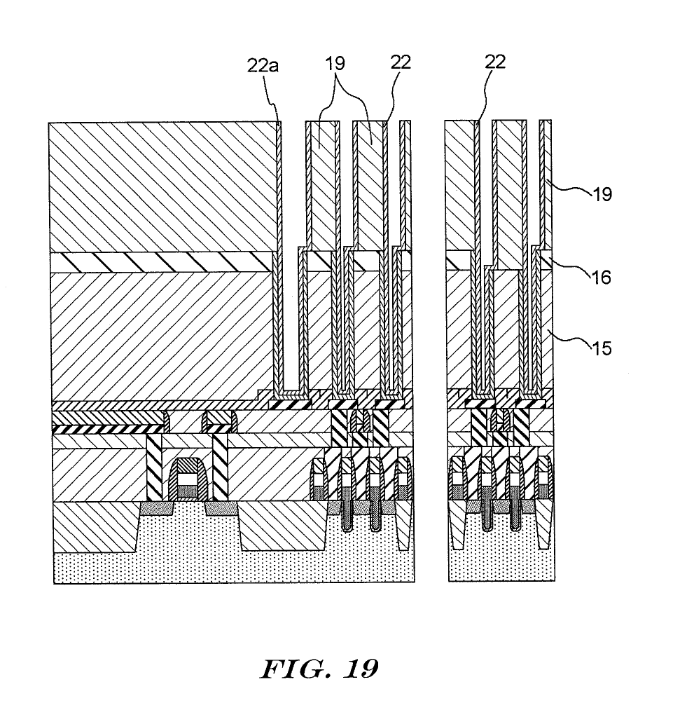

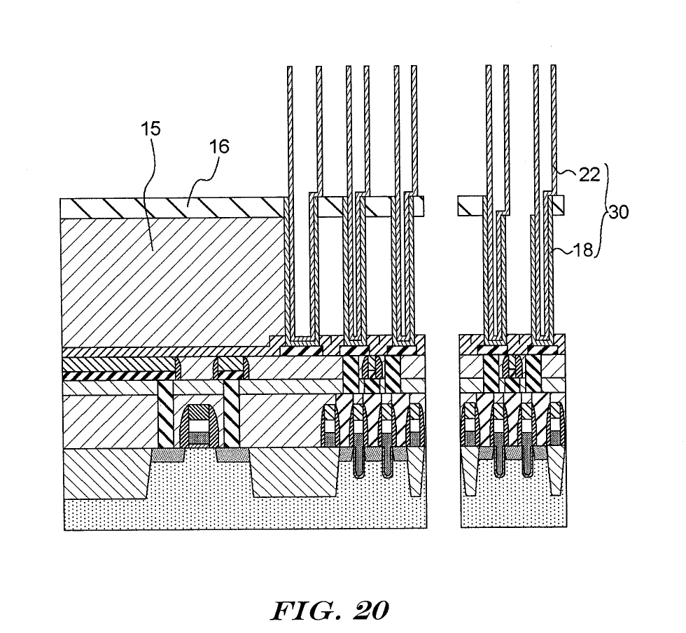

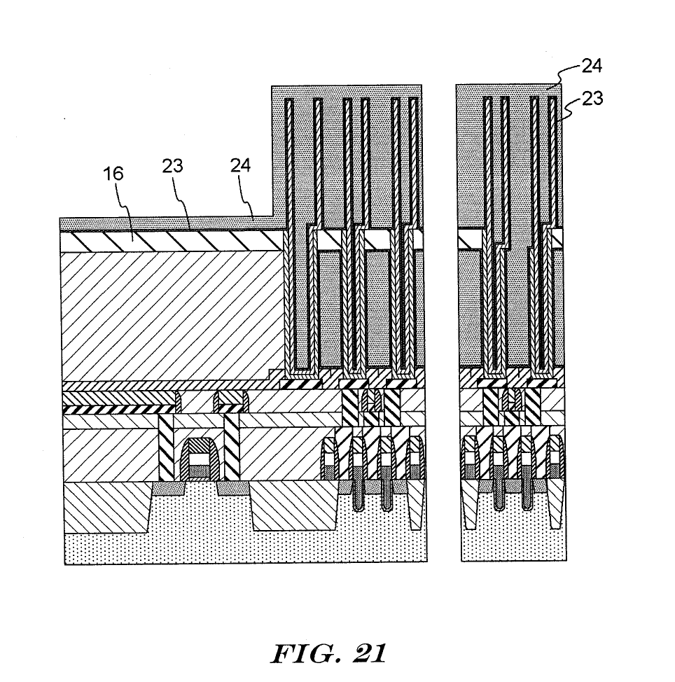

Although in the first and second exemplary embodiment, the first and second supporting films are formed to support the first and second lower electrodes respectively, the second supporting film is not formed but the first supporting film is formed because the lower portion of the second lower electrode is in contact with the inner wall of the first lower electrode. In this case, opening 16B as shown in FIG. 5 is not formed in the peripheral circuit region but the first supporting film remains in the peripheral circuit region as shown in FIG. 18.

Next, as in the first exemplary embodiment, second interlayer insulating film 19 is formed so as not to fill the space laterally surrounded with first lower electrode 18 and then second cylinder hole 21 and second groove 21a are formed in second interlayer insulating film 19. The second lower electrode material with the thickness set not to completely fill second cylinder hole 21 is formed on second interlayer insulating film 19 and on the inner walls of second cylinder hole 21 and second groove 21a and on first lower electrodes 18, 18a. Subsequently, second lower electrodes 20, 20a are formed by removing the second lower electrode material on second interlayer insulating film 19. In this exemplary embodiment, the second supporting film is not formed as shown in FIG. 19.

Next, as in the first exemplary embodiment, second interlayer insulating film 19 is removed and then first interlayer insulating film 15 is further removed by moving the etchant through openings 16A as shown in FIG. 20. At this time, the top face of the first interlayer insulating film at the peripheral circuit region is covered with first supporting film 16 and the side wall thereof is covered with first lower electrode 18a formed in first groove 17a. Therefore, the invasion of the etchant into the peripheral circuit region can be suppressed.

As shown in FIG. 21, capacitive insulating film 23 is formed on the surfaces of lower electrodes 30, 30a and then upper electrode (plate electrode) 24 made of a titanium nitride film is formed on capacitive insulating film 23.

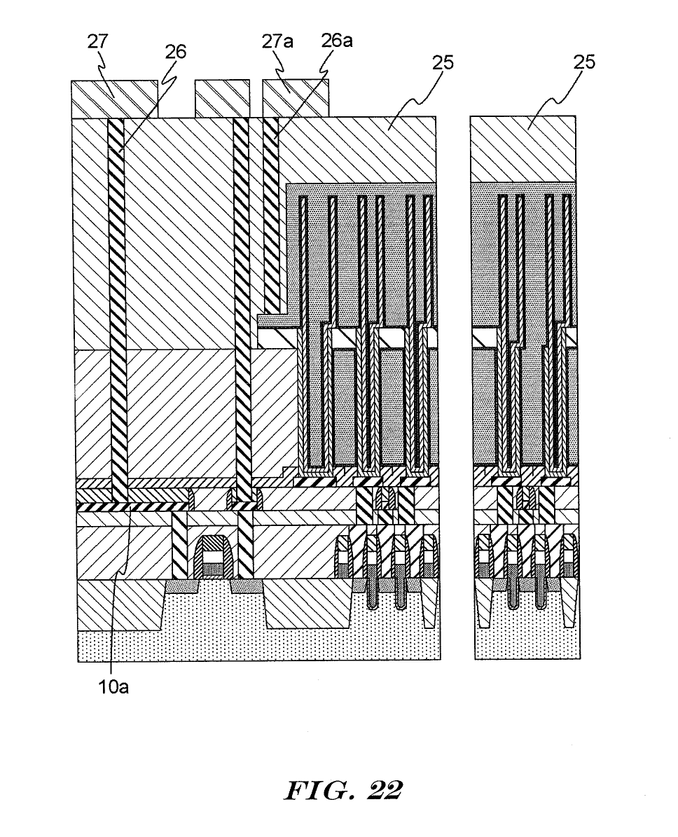

As shown in FIG. 22, the unnecessary films (upper electrode 24, capacitive insulating film 23, and first supporting film 16) in the peripheral circuit region are removed using the photolithography and dry etching techniques. Thereafter, upper electrode 24 is covered with third interlayer insulating film 25 and then the top face of third interlayer insulating film 25 is planarized using a CMP method. In the peripheral circuit region, contact plug 26 reaching peripheral interconnection layer 10a and then metal interconnection layer 27 thereon are formed sequentially. Contact plug 26a and metal interconnection layer 27a are formed in the memory cell region so as to connect with a circuit for applying a given voltage to upper electrode 24.

Additional interconnections and electrodes are manufactured on the resulting structure using the above mentioned method and then a protection film covering the surface thereof is formed, whereby completing the DRAM device as the semiconductor device.

In accordance with this exemplary embodiment, the process of forming the second supporting film is omitted and hence a number of the process can be reduced and further the area of the electrode increase by the area of the top surface of the second lower electrode which is not covered with the second supporting film.

Furthermore, in a variation of this exemplary embodiment, the first supporting film is not formed while the second supporting film is formed. In this case, the method of fabricating the second supporting film is the same as in the first exemplary embodiment. In case the lower electrode is formed with the multi-layered electrodes of 3 or more levels, the supporting film can be formed in each level or some level of the supporting film can be omitted. Anyway, it should suffice to prevent the electrode(s) from collapsing when the interlayer insulating film(s) is removed to expose the outer wall of the electrode.

In this exemplary embodiment, the second lower electrode fills the space laterally surrounded with the first lower electrode as in the second exemplary embodiment.

Although in the previous exemplary embodiments, stopper film 14 remains in the peripheral circuit region, stopper film 14 may be in advance removed, if the stopper film is thick, in the peripheral circuit in order to facilitate the forming of contact plug 26 in a subsequent process.

Although in the previous exemplary embodiments, there is illustrated the semiconductor device such as the DRAM device having the peripheral circuit region and the memory cell region on the same substrate, the invention is not limited to this, and the invention is applied to a configuration in which only the memory cell region exists. In the case, the first and second grooves in the previous exemplary embodiments may be omitted.

Moreover, in case the interlayer insulating film such as the first or second interlayer insulating film is formed as a multi-layered structure, the supporting film may be interposed between the multi-layer and hence the supporting film supports the lower electrode at a middle portion thereof differently from the previous exemplary embodiments where the supporting film supports the lower electrode at the upper end thereof.

What is claimed is:

1. A semiconductor device comprising a capacitor having a lower electrode,
wherein the lower electrode comprises:
a first cylindrical lower electrode connected to a contact electrically connected to a semiconductor substrate; and
a second cylindrical lower electrode in contact with an inner wall of at least an upper end of the first cylindrical lower electrode and extending upwards from a top of the first cylindrical lower electrode.

2. The semiconductor device according to claim 1, wherein the second cylindrical lower electrode is in contact with the entirety of the inner wall of the first cylindrical lower electrode.

3. The semiconductor device according to claim 2, wherein the second cylindrical lower electrode surrounds a void at a region in contact with the inner wall of the first cylindrical lower electrode.

4. The semiconductor device according to claim 1, wherein a region laterally surrounded with the inner wall of the first cylindrical lower electrode is, in at least an upper portion thereof, blocked with the second cylindrical lower electrode.

5. The semiconductor device according to claim 1, wherein the capacitor comprises:
a capacitive insulating film formed on inner and outer walls of the lower electrode; and
an upper electrode formed on the capacitive insulating film.

6. The semiconductor device according to claim 2, wherein the capacitor comprises:
a capacitive insulating film formed on inner wall of the second cylindrical lower electrode and outer walls of the first and second lower electrode; and
an upper electrode formed on the capacitive insulating film.

7. The semiconductor device according to claim 1, wherein the semiconductor device comprises a memory cell region including the capacitor and a peripheral circuit region including other circuits than a memory cell array;
wherein the semiconductor device further comprises, in an end portion of the memory cell region positioned at a boundary between the memory cell region and the peripheral circuit region:
a first gutter-shape lower electrode; and
a second gutter-shape lower electrode in contact with an inner wall of at least an upper end of the first gutter-shape lower electrode and extending upwards from a top of the first gutter-shape lower electrode.

8. A semiconductor device comprising a capacitor having a lower electrode,
wherein the lower electrode comprises:
a lower layer having a stacked structure of at least two conductive films and is connected to a contact electrically connected to a semiconductor substrate; and
a cylindrical upper layer in which an inner side conductive film among the at least two conductive films extends upwards from a top of the lower layer.

9. The semiconductor device according to claim 8, further comprising, between neighboring lower electrodes, an insulating supporting film coupled to outer walls of the lower electrodes.

10. The semiconductor device according to claim 8, wherein the semiconductor device comprises a memory cell region including the capacitor and a peripheral circuit region including other circuits than a memory cell array;
wherein the semiconductor device further comprises a gutter-shape lower electrode in an end portion of the memory cell region positioned at a boundary between the memory cell region and the peripheral circuit region; and
the gutter-shape lower electrode comprises:
a lower layer having a stacked structure of at least two conductive films, and
a gutter-shape upper layer in which an inner side conductive film among the at least two conductive films extends upwards from a top of the lower layer.

11. A method of manufacturing a semiconductor device including a capacitor, comprising:
forming, in a first interlayer insulating film formed on a contact electrically connected to a semiconductor substrate, a first cylinder hole exposing a top face of the contact;
forming, in the first cylinder hole, a first cylindrical lower electrode connected to a contact;
forming a second interlayer insulating film on the first interlayer insulating film so that a space laterally surrounded with the first cylindrical lower electrode is not filled with the second interlayer insulating film;
forming a second cylinder hole in the second interlayer insulating film so as to expose an entirety of an aperture of the space laterally surrounded with the first cylindrical lower electrode and expose an inner wall of the first cylindrical lower electrode; and
forming a second cylindrical lower electrode continuously extending on and from the inner wall of the first cylindrical lower electrode on and to an inner wall of the second cylinder hole, the second cylindrical lower electrode extending cylindrically at least in the second cylinder hole.

12. The method according to claim 11, wherein the second interlayer insulating film is formed using a PE-CVD method at least at first until an upper end of a space laterally surrounded with the first cylindrical lower electrode is blocked with the second interlayer insulating film.

13. The method according to claim 11, wherein the second cylindrical lower electrode is formed on the entirety of the inner wall of the first cylindrical lower electrode.

14. The method according to claim 11, wherein a thickness of the second cylindrical lower electrode is set so as to block an upper end of a space laterally surrounded with the first cylindrical lower electrode.

15. The method according to claim 11, further comprising:
removing the first and second interlayer insulating films around the first and second cylindrical lower electrodes; and
forming a capacitive insulating film on an inner wall of the second cylindrical lower electrode and on outer walls of the first and second cylindrical lower electrodes; and
forming an upper electrode on the capacitive insulating film.

16. The method according to claim 15, wherein at least one of the first and second cylinder holes is formed, after a supporting film preventing the lower electrode from collapsing in removing the interlayer insulating films is formed on or in the interlayer insulating film in which each cylinder hole is formed, so as to penetrate through the supporting film.

17. The method according to claim 11, wherein the semiconductor device comprises a memory cell region including the capacitor and a peripheral circuit region including other circuits than a memory cell array;
wherein in an end portion of the memory cell region positioned at a boundary between the memory cell region and the peripheral circuit region, separate first and second grooves are formed in the first and second interlayer insulating films respectively at the same time as in forming the first and second cylinder holes;
wherein first and second lower electrode materials are formed on the inner walls of the first and second grooves respectively; and
the second lower electrode material is in contact with an inner wall of the first lower electrode material.
